(19) United States
(12) Patent Application Publication
(10) Pub. No.: US 2012/0112603 A1
(43) Pub. Date: May 10, 2012

(54) ELECTROMECHANICAL TRANSDUCER AND METHOD OF FABRICATING THE SAME

(75) Inventor: Yuichi Masaki, Kawasaki-shi (JP)

(73) Assignee: CANON KABUSHIKI KAISHA, Tokyo (JP)

(21) Appl. No.: 13/280,269

(22) Filed: Oct. 24, 2011

(30) Foreign Application Priority Data
Nov. 4, 2010 (JP) 2010-246980

(51) Int. Cl. H02N 1/00; H01L 21/28; H01L 21/306

(52) U.S. Cl. 310/308; 438/22; 438/50; 257/E21.158; 257/E21.219

(57) ABSTRACT

There is provided an electromechanical transducer capable of improving yield and obtaining a cavity having a good internal flatness, and a method of fabricating the same. The electromechanical transducer is fabricated in such a manner that an SOI substrate 209 having an active layer 210 whose surface is planarized on a supporting substrate 201 with a thermal oxide insulating layer 205 interposed therebetween is provided; the active layer is patterned into a cavity shape; insulating films 206 and 207 are formed on the patterned active layer; an etching hole 203 passing through the insulating films and communicating with the active layer is formed; and a cavity 202 is formed by etching away the active layer using the etching hole.

### BACKGROUND OF THE INVENTION

1. Field of the Invention

The present invention relates to an electromechanical transducer such as a capacitive ultrasound transducer of converting mechanical vibrations to an electrical signal or converting an electrical signal to mechanical vibrations, and a method of fabricating the same using micromachining process.

2. Description of the Related Art

Recent years have seen studies on a capacitive micromachined ultrasonic transducer (CMUT) fabricated by micromachining process for use as an ultrasound probe in medical imaging. The CMUT is a device formed of, for example, a lower electrode; a light-weight diaphragm supported above the lower electrode at a predetermined spacing; and an upper electrode disposed on a surface of the diaphragm, and it uses the diaphragm to transmit and receive ultrasound. Due to an excellent broadband characteristics and high sensitivity characteristics of the device, a medical diagnosis using the CMUT can provide higher precision than a diagnosis using a conventional piezoelectric device. The CMUT operation principle is as follows. When a DC voltage with a minute AC voltage superimposed thereon is applied to between the lower electrode and the upper electrode, ultrasound is generated and transmitted from the diaphragm. Conversely, when ultrasound is received, the diaphragm is deformed by the ultrasound and the deformation changes the capacity between the lower electrode and the upper electrode, so that a signal is detected.

There is proposed a CMUT fabrication method in which a cavity structure is formed on a silicon substrate, an SOI (Silicon-On-Insulator) substrate is bonded to the silicon substrate under vacuum, and only a single crystal silicon membrane of the SOI substrate is left as a diaphragm (U.S. Pat. No. 6,958,255). There is also proposed another CMUT fabrication method in which a deposited silicon nitride (SiN) film is used as a diaphragm; and after an etching hole is formed, a sacrificial layer is etched away to form a cavity; and finally the etching hole is sealed by vacuum coating (U.S. Pat. No. 5,619,476).

### SUMMARY OF THE INVENTION

The sensor performance of the CMUT is determined by uniform operation of a capacitance group including a large number of cavities disposed on a substrate. The uniform capacitance group requires a uniform gap between the upper and lower electrodes of each cavity, a smooth surface roughness of the facing surfaces, and uniform mechanical characteristics (Young's modulus, Poisson's ratio, density, and the like) of the diaphragm. Further, in the CMUT, an increase in DC bias application causes the diaphragm to be deformed due to electrostatic attraction. If the diaphragm contacts a bottom surface of the cavity due to the deformation, charging phenomena due to charge transfer occur, which varies the characteristics, thereby greatly deteriorating the device performance. According to U.S. Pat. No. 6,958,255 having a configuration of using the single crystal silicon membrane as the diaphragm, the silicon surface planarized by CMP (Chemical Mechanical Polish) is used as an inner wall surface of the cavity, and thus each cavity can have a uniform gap. However, the bonding process during fabrication requires very precise cleaning enough to completely remove particles, and further requires an anneal process at high temperatures (about 1000° C.). Unfortunately, since gases generated in a bonding interface adversely affect the diaphragm, the configuration remains difficulties in yield improvement. Further, the fabrication method using surface micro-machining as disclosed in U.S. Pat. No. 5,619,476 also has problems as follows. The process of a multiple use of thin film formation and patterning, particularly, formation of a SiN film for use as the diaphragm while controlling residual stress by means of a plasma CVD (plasma enhanced Chemical Vapor Deposition) apparatus, enables a relatively good yield of uniform cavity formation. However, a thin film lamination may deteriorate uniformity of the film thickness of the diaphragm or the side wall constituting a part of the cavity. Thus, the uniformity of the film thickness is generally lower than the flatness of the CMUT fabricated by the bonding.

In view of the above problems, a method of the present invention for fabricating an electromechanical transducer such as a capacitive ultrasound transducer includes at least: providing an SOI substrate having an active layer whose surface is planarized on a supporting substrate with an insulating layer interposed therebetween; patterning the active layer into a cavity shape; forming an first insulating film on the patterned active layer; forming an etching hole passing through the first insulating film and communicating with the active layer; and forming a cavity by etching away the active layer using the etching hole.

In view of the above problems, an electromechanical transducer of the present invention such as a capacitive ultrasound transducer includes a plurality of elements having at least one cell composed of a substrate, a diaphragm, and a diaphragm support portion. The substrate is an SOI substrate from which an active layer is removed. The diaphragm support portion supports the diaphragm such that a cavity is formed between a surface of an insulating layer of the substrate and the diaphragm.

The present invention can eliminate the need for the bonding process and the effects of particles and gasses generated in a bonding interface, and can increase yield. Further, the use of an active layer with good flatness of the SOI substrate as a sacrificial layer can improve the surface roughness inside the cavity.

Further features of the present invention will become apparent from the following description of exemplary embodiments with reference to the attached drawings.

### BRIEF DESCRIPTION OF THE DRAWINGS

FIG. 1A is a top view describing a CMUT according to a first example of the present invention.

FIG. 1B is a sectional view describing the CMUT according to the first example of the present invention.

FIGS. 2A, 2B, 2C, 2D, 2E, 2F, 2G, and 2H are a sectional view describing a fabrication method according to the first example of the present invention.

FIGS. 3A and 3B are sectional views describing a CMUT according to a second example of the present invention and a method of fabricating the same.

FIGS. 4A and 4B are sectional views describing a CMUT according to a third example of the present invention and a method of fabricating the same.

FIGS. 5A, 5B, 5C, 5D and 5E illustrate the characteristic measurement method, the operation principle, and the characteristic measurement result data of the CMUT.

### DESCRIPTION OF THE EMBODIMENTS

Preferred embodiments of the present invention will now be described in detail in accordance with the accompanying drawings.

The electromechanical transducer of the present invention and the method of fabricating the same are characterized by using an active layer of an SOI substrate with good flatness provided by a CMP as a sacrificial layer for forming a cavity. Based on the above concept, the electromechanical transducer of the present invention and the method of fabricating the same have a basic configuration as described in SUMMARY OF THE INVENTION. Typically, further, the present invention is characterized in that a SiO₂ film is formed on an upper surface of the active layer by a vapor-phase growth method such as a CVD process and a sputtering process and thermal oxidation followed by other insulating film formation, and then the Si active layer is removed to fabricate an electromechanical transducer by surface micro-machining.

The mode for carrying out the present invention will be described referring to the following examples.

### First Example

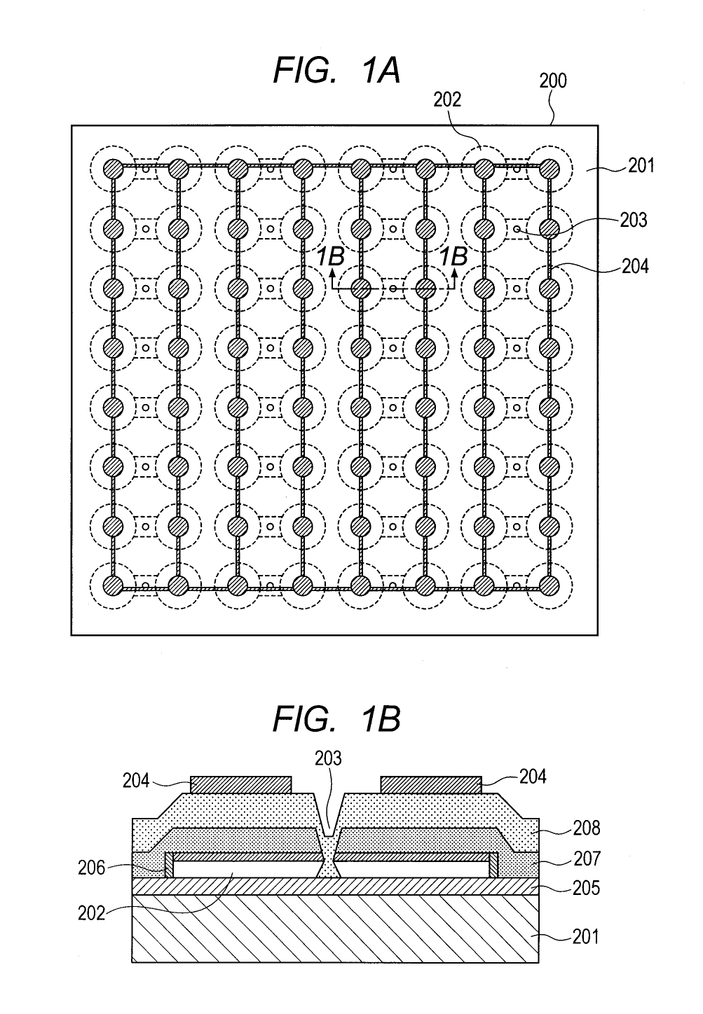

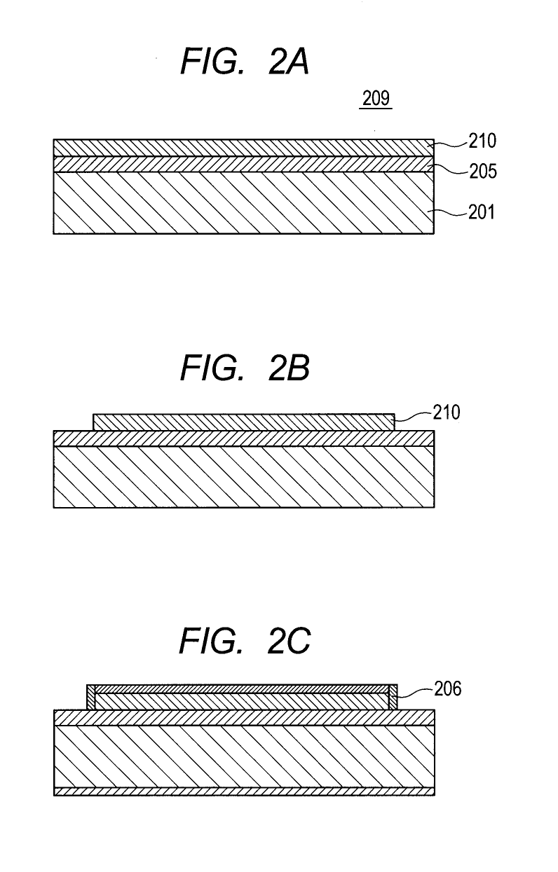

A method of fabricating a CMUT according to a first example will be described referring to the accompanying drawings. FIG. 1A is a top view illustrating an example of an entire CMUT element 200. As illustrated in FIG. 1A, the first example is configured such that a group of 8×8 cavities 202 is formed on a supporting substrate of an SOI substrate serving as a lower electrode. Here, a pair of two cavities 202 shares an etching hole 203, and an aluminum upper electrode 204 is formed on the upper most layer. The mentioned configuration can be also referred to in FIG. 1B. FIG. 1B is a sectional view taken along line 1B-1B of FIG. 1A. FIG. 1B also illustrates a SiO₂ layer 205, a thermal oxide film (SiO₂ film) 206, a SiN diaphragm 207, and a SiN sealing/vibrating diaphragm 208 on a supporting substrate 201.

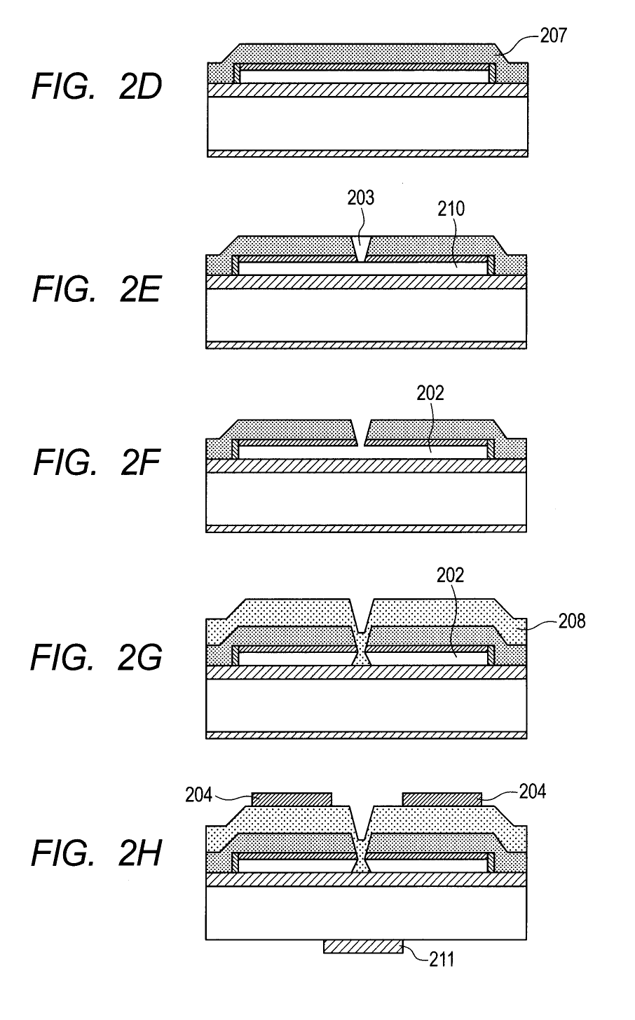

The fabrication method according to the present example will be described referring to FIGS. 2A, 2B, 2C, 2D, 2E, 2F, 2G, and 2H. Although these process drawings illustrate partial sections for the sake of brevity of description, other portions can also be fabricated in the same manner. First, an SOI substrate was provided. FIG. 2A illustrates a 4-inch SOI substrate 209 used in the present example. The substrate was configured such that an active layer 210 had a film thickness of 200 nm, the insulating layer (SiO₂ layer) 205 had a film thickness of 100 nm, and the supporting substrate 201 had a film thickness of 400 μm. The supporting substrate 201 was phosphorus-diffused n-type silicon with a resistance of 10 mΩ-cm. As shown herein, the SOI substrate 209 had the active layer 210 whose surface was planarized on the supporting substrate 201 with the insulating layer 205 interposed therebetween. Note that the above specification is just an example for the purpose of description and it should be changed depending on the operation design as the CMUT. Note also that boron-diffused p-type silicon may be used as the supporting substrate.

Then, the active layer 210 was patterned into a cavity shape. FIG. 2B illustrates a state of completing the patterning of the active layer 210 into a shape having two cavities with a diameter of 40 μmΦ and a flow path with a width of 10 μm and a length of 10 μm communicating therebetween. Specifically, the silicon active layer 210 was dry-etched from a resist image formed by a photolithography process. The dry-etching was performed under the conditions of the etching gas of SF₆ at the flow rate of 200 sccm, the pressure of 3 Pa, the RF power of 400 W, and the etching time of 200 seconds.

FIG. 2C illustrates a state of completing the formation of the insulating film 206 by thermal oxidation. Specifically, for cleaning, a solution of a mixture of sulfuric acid and hydrogen peroxide in the ratio of 90:10 was heated to 120° C., and the substrate was dipped in the solution for 20 minutes followed by sufficient pure water cleaning and drying to complete the removal of resist residues and organic particles. Then, the substrate was placed in an oxidation furnace in which the substrate was heated at a temperature of 1000° C. for 15 minutes in an oxygen gas at the flow rate of three liters per minute to form a 100-nm-thick SiO₂ film 206.

FIG. 2D illustrates a state of completing the formation of a 200-nm-thick SiN film 207 on the SiO₂ film 206 and the insulating layer (SiO₂ layer) 205 by a plasma CVD apparatus (model CC-200 manufactured by ULVAC). The film was formed under the conditions of the SiH₄ gas at the flow rate of 42 sccm, the NH₃ gas at the flow rate of 20 sccm, the N₂ gas at the flow rate of 80 sccm, the substrate temperature of 350° C., the RF power of 300 W, and the etching time of 120 seconds. The plasma CVD apparatus of the present example had a process condition of assuming the residual stress of the SiN film 207 as low tension stress (about 100 MPa or less), but the stress control can be performed by changing other parameters. Note that instead of the plasma CVD apparatus, a low pressure CVD apparatus may be used for film formation.

FIG. 2E illustrates a state of completing the formation of the etching hole 203 with an opening diameter of 6 μmΦ for removing silicon of the active layer 210 serving as the sacrificial layer. A predetermined etching hole resist image was formed by a photolithography process, and then the SiN film 207 and the SiO₂ film 206 were etched. Specifically, the films were etched by a chemical dry etcher under the conditions of the etching gases of CF₄ at the flow rate of 300 sccm, O₂ at the flow rate of 240 sccm, and N₂ at the flow rate of 80 sccm, the pressure of 60 Pa, the RF power of 700 W, and the etching time of 180 seconds. Thus, an etching hole passing through the insulating films and communicating with the active layer was formed.

FIG. 2F illustrates a state of completing the formation of the cavity 202. A dry etcher was used under the process conditions of the etching gas of XeF₂ at the flow rate of 80 sccm, the pressure of 40 Pa, the etching time of three minutes to completely etch away the silicon 210 as the sacrificial layer through the etching hole 203. Note that although in this example the XeF₂ gas was used to etch away the silicon sacrificial layer through the etching hole 203, a wet etching process such as an alkaline solution can be used for removal.

FIG. 2G illustrates a state of completing the sealing of the etching hole 203 by forming a 500-nm-thick SiN film 208 again by the plasma CVD apparatus. The film was formed for the same 300 seconds, when the SiN film 207 was formed as illustrated in FIG. 2D. Here, the SiN film 208 is also added to the CMUT diaphragm, and thus the residual stress of the film 208 needs to be tension stress.

FIG. 2H illustrates the final process indicating a state of completing the formation of a pattern of the upper electrodes 204 made of an aluminum film (100 nm thick) on upper portions of the cavity. A sputtering apparatus was used to complete the formation of the 100 nm thick film using an aluminum target under the conditions of the Ar gas at the flow rate of 30 sccm, the pressure of 0.7 Pa, the RF power of 400 W, and the etching time of 200 seconds. Subsequently, a resist image was formed on a predetermined pattern of the upper electrode 204 by a photolithography process. Then, a mixed acid aluminum etchant (etchant solution TSL manufactured by Hayashi Pure Chemical Ind., Ltd.,) was heated to 45° C., and etching was performed for an etching time of 60 seconds. Note that a dilute hydrofluoric acid solution was used to remove an oxide film from the rear surface as well. Likewise, the sputtering apparatus was used to form a lower electrode removing pad 211 through a SUS stencil mask. Thus, the CMUT fabrication process of the present example completed. This led to fabrication of an electromechanical transducer having a plurality of elements including at least one cell composed of a substrate having an SOI substrate whose active layer was removed, a diaphragm, and a diaphragm support portion. The diaphragm support portion was supporting the diaphragm so as to form a cavity between a surface of the insulating layer of the substrate and the diaphragm. In addition, the diaphragm of the present example included the insulating film formed by thermal oxidation and other insulating films formed on the insulating film by a vapor-phase growth method such as a CVD method and a sputtering method.

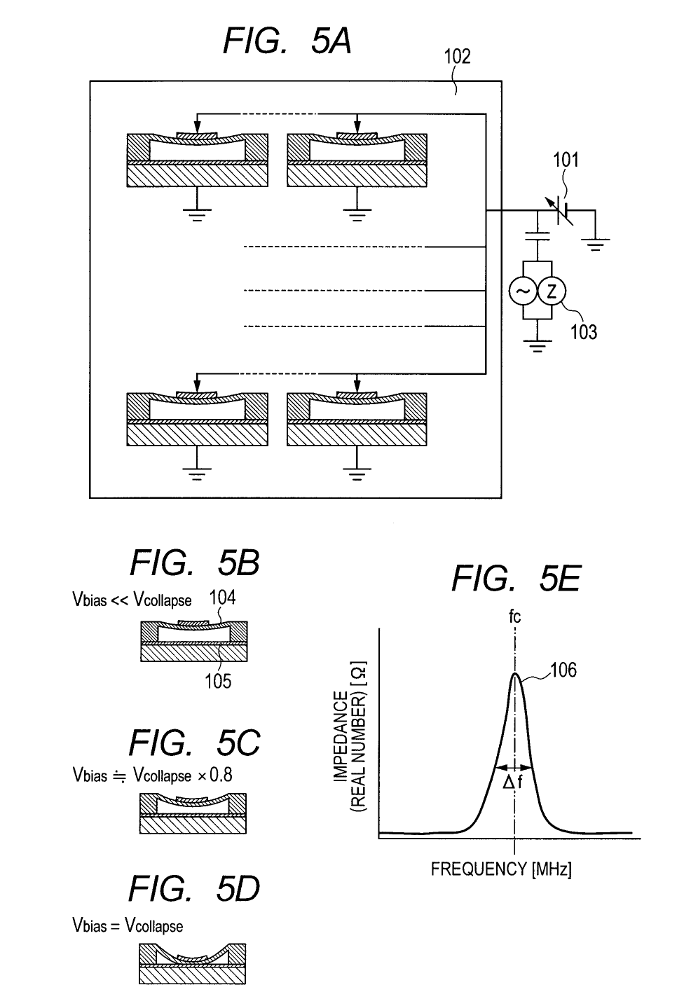

Meanwhile, the conventional CMUT by surface micro-machining advantageous in fabrication yield has the following two major problems. A first problem is a low flatness inside the fabricated cavity. When various thin films were formed on silicon substrates with good flatness provided by a CMP process to measure the surface roughness of the film by means of a scanning probe microscope (SPM), the result showed that the surface roughness of each silicon surface was deteriorated. As illustrated in FIG. 5A, frequency characteristics of the CMUT 102 were measured for each element by an impedance analyzer 103 while a DC bias was applied from an external power supply 101. The measurements were performed by changing the DC bias as illustrated in FIGS. 5B, 5C, and 5D. Here, the DC bias value when the diaphragm 104 contacts the lower electrode 105 due to electrostatic attraction is referred to as a collapse voltage (=V collapse). A Q value (=center frequency fc/full width at half maximum of the peak Δf) indicating the variation of the cavity group in an element was obtained from a peak curve 106 (illustrated in FIG. 5E) of a resonance frequency immediately before the collapse voltage. The higher the gap uniformity is, the higher the Q value is. The above measurements revealed that an improvement in surface roughness of the thin film formed by polishing did not improve the CMP processed surface of single crystal silicon due to particle aggregate of the material. Further, it was found that while a method of accelerating gaseous atoms to irradiate the thin film surface by means of gas cluster ion beam (GCIB) technique improved the surface roughness at low frequency (space wavelength 0.1 to 1.0 μm), the technic did not sufficiently improve fine roughness as a problem to be solved.

A second problem is a large amount of charge injection of an insulating material constituting the cavity. Conventionally, since a SiO₂ film cannot be formed by thermal oxidation except the substrate surface, an insulating film material in surface micro-machining even for use in a silicon substrate is limited to a SiN film or a SiO₂ film by a plasma CVD or a low pressure CVD. In general, a SiO₂ film by thermal oxidation is fabricated as less defective quality oxide film by oxidation of single crystal silicon. Thus, concerning an external charge, the charge is only trapped in a small amount of defects and the amount of charge injection is smaller than the other thin film insulating materials such as SiN. In the CMUT in which the facing surfaces are configured with a small gap, even if the diaphragm deformed by electrostatic attraction due to an applied DC bias contacts the bottom surface of the cavity, the charge amount is very small due to the SiO₂ characteristics, and thus the characteristic variation in a large number of cavities can be suppressed.

The present example can solve the first and second problems. Specifically, it was confirmed by a cross-sectional transparent electron microscope (TEM) that when the cavity 202 formed by the CMUT of the present example was broken, it was found that the inner wall was covered with a thermal oxide film (SiO₂ film 206). Further, it was confirmed by an SPM that the surface roughness of the bottom surface inside the cavity 202 and the surface roughness of the top surface thereof were very flat with Ra=about 0.2 nm. Further, the amount of charge injection of the SiO₂ film 206 of the insulating material constituting the cavity was reduced (the charge characteristics were improved). Furthermore, the present example eliminated the substrate bonding process and was not affected by particles and gases generated in a bonding interface and conventionally causing a defect, thereby enabling an improvement in yield.

Thus, the present example enables configuration using an insulating film material having the same quality as that of the surface roughness inside the cavity which is the same as CMUT fabricated by bonding and can achieve a very high performance CMUT by surface micro-machining process. Thus, the present example can provide an electromechanical transducer such as a capacitive ultrasound transducer having good yield and good characteristics.

### Second Example

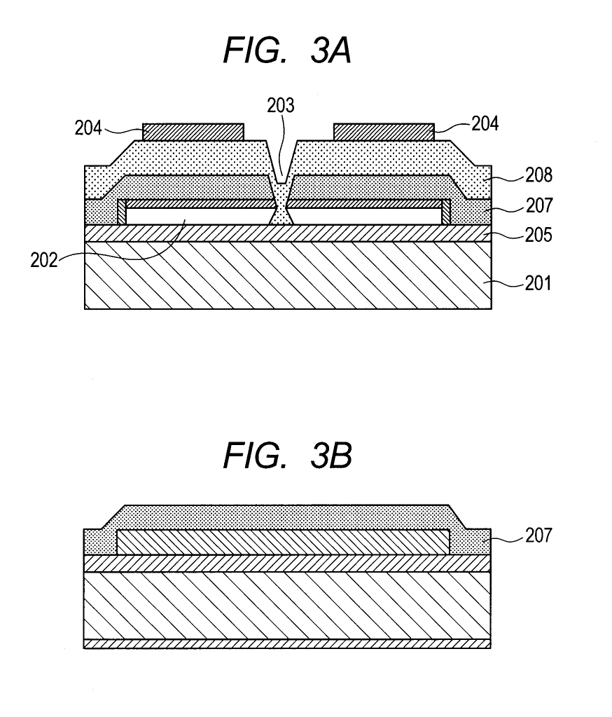

A method of fabricating a CMUT according to a second example is as follows. In the second example, a thermal oxide SiO₂ film 206 is not formed. A top view of an entire element of a CMUT fabricated according to the second example is the same as that of FIG. 1A. FIG. 3A is a sectional view taken along line 1B-1B of the second example. FIG. 3A illustrates a supporting substrate 201 of an SOI substrate, a SiO₂ layer 205 of the SOI substrate, a cavity 202, a cavity etching hole 203, a SiN diaphragm 207, a SiN sealing/diaphragm 208, and an aluminum upper electrode 204 as well.

In this example, the SOI substrate 209 for use in the second example had an active layer 210 with a film thickness of 160 nm, so that the gap value of a cavity when the CMUT completes is the same as that of the first example. Note that while it is not necessary to realize the same gap value, it is for the sake of a convenient for performance comparison between the two examples described later. The present example performed the same processes as described in the first example referring to FIGS. 2A and 2B to fabricate a cavity pattern of the active layer.

FIG. 3B illustrates a state of completing the formation of a 300-nm-thick SiN film 207 by the plasma CVD apparatus (model CC-200 manufactured by ULVAC). The insulating film had the same film thickness as that in the first example. The film was formed under the conditions of the SiH₄ gas at the flow rate of 42 sccm, the NH₃ gas at the flow rate of 20 sccm, the substrate temperature of 350° C., the RF power of 300 W, and the etching time of 180 seconds. The second example also had a process condition of assuming the residual stress of the SiN film as tension stress (about 100 MPa or less). Note that instead of the plasma CVD apparatus, also in this example, a low pressure CVD apparatus may be used to form the SiN film.

The second example followed the same processes as described in the first example referring to FIGS. 2E to 2H followed after the above processes to complete the CMUT fabrication process of the second example. Specifically, the present example did not form a thermal oxide SiO₂ film 206, but performed a process of forming another insulating film 207 on a patterned active layer before a process of forming the insulating film 208 on a patterned active layer. It was confirmed in the CMUT of the present example that the surface roughness of the bottom surface inside the formed cavity was very flat with Ra=about 0.2 nm, but the surface roughness of the top surface thereof was less flat than that of the first example with Ra=about 0.8 nm. A conceivable reason for this surface roughness is that the selection ratio between Si (active layer) and SiN at the time of etching the sacrificial layer is less than the selection ratio between Si (active layer) and thermal oxide SiO₂.

### Third Example

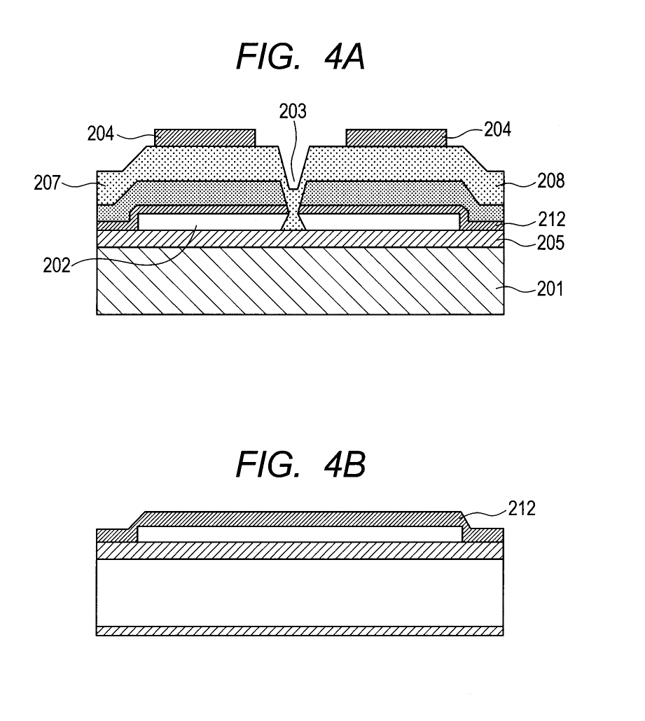

A method of fabricating a CMUT according to a third example is as follows. In the third example, a SiO₂ film 212 is formed instead of a thermal oxide SiO₂ film 206. A top view of an entire element of a CMUT fabricated according to the third example is the same as that of FIG. 1A. FIG. 4A is a sectional view taken along line 1B-1B of the third example. FIG. 4A illustrates a supporting substrate 201 of an SOI substrate, a SiO₂ layer 205, a cavity 202, a cavity etching hole 203, a SiO₂ film 206, a SiN diaphragm 207, a SiN sealing/diaphragm 208, and an aluminum upper electrode 204 as well.

The fabrication method according to the third example is as follows. The SOI substrate 209 for use in the third example had an active layer 210 with a film thickness of 160 nm, so that the gap value of the cavity 202 when the CMUT completes is the same as that of the above examples. The fabrication was performed under same conditions up to a process of forming a cavity pattern of the active layer described in the first example. FIG. 4B illustrates a state of completing the formation of a 100-nm-thick SiO₂ film 212 by the plasma CVD apparatus (model CC-200 manufactured by ULVAC). The film was formed under the conditions of the SiH₄ gas at the flow rate of 45 sccm, the N₂O gas at the flow rate of 90 sccm, the substrate temperature of 350° C., the RF power of 400 W, and the etching time of 30 seconds.

The same processes as described in the first example referring to FIGS. 2E to 2H followed after the above processes to complete the CMUT fabrication process of the third example. Specifically, a SiO₂ film 212 is formed instead of the thermal oxide SiO₂ film 206, and performed a process of forming an insulating film 207 on a patterned active layer before a process of forming another insulating film 208 on a patterned active layer. It was confirmed that the surface roughness of the bottom surface inside the cavity formed by the CMUT of the present example and the surface roughness of the top surface thereof were very flat with Ra=about 0.2 nm. However, the charge characteristic (charge voltage) of the diaphragm was lower than that of the first example.

Three samples fabricated according to the above three examples (first, second, and third examples) were evaluated and the evaluated performance results are listed in the following Table 1. It is understood from Table 1 that, as initial characteristics, the Q value of the second example was relatively low, and it is understood that the XeF₂ gas at the time of etching the sacrificial layer caused a rough surface of the SiN film. The charge characteristics of the second and third examples were lower than that of the first example as understood from the description about the second problem. It indicates that, as described above, the thermal oxide SiO₂ film is advantageous as the insulating film. Note that since the active layer of the SOI substrate with good flatness as the sacrificial layer for forming the cavity is used in the second and third examples, the surface roughness inside the cavity was better than that by conventional surface micro-machining.

TABLE 1

| | SURFACE | | | | | FULL | |
|---|---|---|---|---|---|---|---|
| | ROUGHNESS INSIDE | | | | | WIDTH AT | |
| | CAVITY | | | | RESONANCE | HALF | |
| | BOTTOM | TOP | COLLAPSE | Q | FREQUENCY | MAXIMUM | CHARGE |
| | SURFACE | SURFACE | VOLTAGE | VALUE | fc | Δf | VOLTAGE |
| FIRST | 0.22 | 0.19 | 78 | 264 | 1.56 | 0.0059 | 0.7 |
| EXAMPLE | | | | | | | |
| SECOND | 0.21 | 0.85 | 76 | 112 | 1.68 | 0.0105 | 10 |
| EXAMPLE | | | | | | | |
| THIRD | 0.24 | 0.22 | 76 | 245 | 1.52 | 0.0062 | 5 |
| EXAMPLE | | | | | | | |

| | | | |
|---|---|---|---|
| [nm] | [V] | [MHz] | [V] |

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-246980, filed Nov. 4, 2010, which is hereby incorporated by reference herein in its entirety.

What is claimed is:

1. An electromechanical transducer fabricating method comprising at least:
providing an SOI substrate having an active layer, whose surface is planarized, on a supporting substrate with an insulating layer interposed therebetween;
patterning the active layer into a cavity shape;
forming a first insulating film on the patterned active layer;
forming an etching hole passing through the first insulating film and communicating with the active layer; and
forming a cavity by etching away the active layer through the etching hole.

2. The electromechanical transducer fabricating method according to claim 1, further comprising forming a second insulating film on an upper surface by performing thermal oxidation on the patterned active layer before forming the first insulating film on the patterned active layer.

3. The electromechanical transducer fabricating method according to claim 2, further comprising forming the first insulating film having a tension stress of 100 MPa or less on the second insulating film formed by the thermal oxidation.

4. The electromechanical transducer fabricating method according to claim 1, further comprising forming a third insulating film on the patterned active layer before forming the first insulating film on the patterned active layer.

5. The electromechanical transducer fabricating method according to claim 1, wherein the first insulating film formed on the active layer is a SiN film or a SiO₂ film.

6. The electromechanical transducer fabricating method according to claim 1, further comprising
sealing the etching hole; and
forming an upper electrode pattern on an upper portion of the cavity.

7. An electromechanical transducer comprising a plurality of elements having at least one cell composed of a substrate having an SOI substrate whose active layer is removed, a diaphragm, and a diaphragm support portion supporting the diaphragm so as to form a cavity between a surface of an insulating layer of the substrate and the diaphragm.

8. The electromechanical transducer according to claim 7, wherein the diaphragm comprises an insulating film formed by thermal oxidation and another insulating film formed on the insulating film by a vapor-phase growth method.
